(19) United States
(12) Patent Application Publication
(10) Pub. No.: US 2002/0150270 A1
(43) Pub. Date: Oct. 17, 2002

(54) Sound system having a HF horn coaxially aligned in the mouth of a midrange horn

(75) Inventor: Bernard M. Werner, Los Angeles, CA (US)

Correspondence Address: Squire, Sanders & Dempsey L.L.P., 14th Floor, 801 S. Figueroa Street, Los Angeles, CA, 90017-5554, US

(73) Assignee: Harman International Industries Incorporated

(21) Appl. No.: 10/093,186

(22) Filed: Mar. 7, 2002

Related U.S. Application Data
(60) Provisional application No. 60/273,844, filed on Mar. 7, 2001.

(51) Int. Cl. H03G 5/00; H04R 1/02; H04R 1/20

(52) U.S. Cl. 381/342; 381/99

(57) ABSTRACT

This invention is directed a sound system that groups a midrange horn with a HF horn to increase the sound pressure levels while minimizing interference problems. The HF horn may be coupled to at least two HF drivers where they sum or merge into a common throat or wave-guide. The midrange horn may be coaxially mounted with the higher frequency horn. The midrange horn may be coupled to at least two midrange drivers. And the midrange drivers may be mounted substantially perpendicular to the HF drivers. This configuration provides for smaller system sizes, than conventional mounting of the HF horn adjacent to the mid frequency horn. By coaxially mounting the midrange and HF horns, the off-axis interference (lobing) through the crossover region both in the horizontal and vertical planes may be minimized. This configuration produces increased sound pressure levels while minimizing acoustic crossover interference problems.

### CROSS REFERENCE TO RELATED APPLICATIONS

This application claims priority from a provisional application having Application Serial No. 60/273,844 that was filed on Mar. 7, 2001, and is incorporated by reference.

### BACKGROUND OF THE INVENTION

1. Field of the Invention

This invention provides a sound system capable of grouping midrange and high frequency drivers together in an enclosure to increase the sound pressure level while minimizing interference problems.

2. Related Art

A sound system in a large spacious area such as an arena, outdoor, or stadium setting requires very high sound pressure levels (SPL) for adequate reproduction because of the long distances sound waves must travel in order to reach the listener. With the long distance, however, attenuation may develop in the sound waves. This may cause a drop of about 6 dB level of sound amplitude as sound waves travel twice the distances. Attenuation problems in the sound waves may be overcome by producing higher sound pressure levels at the origination of the sound. One way to do this is through grouping a number of loudspeakers together to increase the SPL.

When a group of loudspeakers generate sound there may be an overlapping in the coverage area. Overlapping sound waves, however, interferer with other sound waves. This can cause the overall SPL produced from the group of loudspeakers to be less than the SPL produced from the individual loudspeakers. For example, two sources or drivers generating overlapping patterns may increase the average SPL to about 3 dB over one of the two sound sources. By comparison, a coherent summation, where there is little or no interference, between two sound sources, would increase the average SPL by about 6 dB over one of the two sound sources. Interference may also reduce the intelligibility and coherency of the sound because the sound waves may be arriving at the listener's ears at different times from different sound sources. Another problem may be reverberation within the auditorium due to sound waves bouncing off the walls, affecting the quality of the sound.

In an attempt to minimize the problems of grouping loudspeakers some have tried to incorporate two or three midrange drivers and two or three high frequency drivers into one enclosure. Such an arrangement helps to raise the SPL but there may still be a problem with interference. Meaning, the drivers do not add up to produce the optimal SPL. Therefore, there still is a need for a sound system that may group midrange and high frequency (HF) drivers to increase the SPL while minimizing interference.

### SUMMARY

This invention provides a sound system that groups a midrange horn with a high frequency (“HF”) horn to increase the sound pressure level (“SPL”) while minimizing interference problems. The sound system may include the following features: (1) a HF horn having at least two HF drivers where they sum or merge into a common throat or wave guide; (2) the HF horn may be coaxially mounted within the mouth of a midrange horn, where the midrange horn has at least two midrange drivers; and/or (3) the midrange drivers may be generally perpendicular to the HF drivers.

The HF horn may be coaxially aligned within the mouth of a midrange horn. For example, the HF horn may include at least two HF drivers or transducers within the mouth of the midrange horn. Each of the two HF drivers may have a vertical diffraction slot opening providing an exit for the sound waves. The two slots from each of the HF drivers may be merged to form a common exit. The shape of the common exit may be rectangular. The two slots may be adjacent to each other and together forming a throat. The two slots may be sized in terms of their height and width, with the vertical centerline for each of the two slots spaced apart from each other, so that the acoustic output of the two slots may be fully coherent. In this configuration, the wave fronts from the two slots may be in phase so that summation of the acoustic wave fronts occurs at frequencies between 500 Hz and 20 kHz and at angles within the nominal horizontal and vertical coverage of the sound system.

The midrange horn throat may be driven by at least two midrange drivers that are arranged so that they are substantially perpendicular to the HF drivers. The midrange drivers may be sized and spaced apart from each other so that the acoustic response combines fully coherent. In this configuration, a more ideal phase summation of the acoustic wave fronts may occur at frequencies between 100 Hz and 2 kHz and at angles within the nominal horizontal and vertical coverage of the sound system.

With the HF horn coaxially positioned within the mouth of the mid-frequency horn, the size of the sound system may be reduced. The coaxial mounting may allow the off-axis interference (lobing) through the crossover region to be optimized equally in both the horizontal and vertical planes. The use of two midrange and two HF drivers may be arranged to sum coherently within the system's coverage angles. This may provide a 6 dB increase in the SPL as compared to a single driver. Therefore, increased SPL may be achieved while minimizing acoustic crossover interference problems.

Other systems, methods, features and advantages of the invention will be or will become apparent to one with skill in the art upon examination of the following figures and detailed description. It is intended that all such additional systems, methods, features and advantages be included within this description, be within the scope of the invention, and be protected by the accompanying claims.

### BRIEF DESCRIPTION OF THE FIGURES

The invention can be better understood with reference to the following figures. The components in the figures are not necessarily to scale, emphasis instead being placed upon illustrating the principles of the invention. Moreover, in the figures, like reference numerals designate corresponding parts throughout the different views.

FIG. 1 is a front view of the sound system with a high frequency horn within a midrange horn.

FIG. 2 is a cross-sectional view of the sound system along a line A-A of FIG. 1 showing a plurality of high frequency drivers.

FIG. 3 is a cross-sectional view of the sound system along a line B-B of FIG. 1 showing a plurality of midrange drivers.

FIG. 4 is a graph of midrange impulse response with and without a damper covering the high frequency drivers of FIG. 2.

FIG. 5 is a front view of the sound system illustrating a radiating area that may be divided into three areas.

FIG. 6 is a front view of the sound system illustrating that as listening location is moved to the left, the vectors that sound travels through moves to the left.

FIG. 7 is a top view of the sound system illustrating the vector moving to the left as shown in FIG. 6.

FIG. 8 is a top cross-sectional view of two high frequency drivers coupled to two slots margining into a common exit.

FIG. 9 is a top cross-sectional view of traditional drivers coupled to two slots.

FIG. 10 is a perspective view of a common exit of two slots.

FIG. 11 is a graph of unprocessed frequency response and impedance curve of a high frequency horn.

FIG. 12 is a graph of horizontal off axis response of a high frequency horn.

FIG. 13 is a graph of high-resolution frequency response of the processed midrange, high frequency, and the net system response.

FIG. 14 is a graph of three horizontal beamwidth curves for unprocessed midrange and high frequency beamwidths, and a processed overall horizontal beamwidth of the system.

FIG. 15 is top view of two slots that are curved.

FIG. 16 is a flow chart of a method for grouping midrange and high frequency drivers together in an enclosure to increase sound pressure level while minimizing interference problems.

### DETAILED DESCRIPTION OF THE PREFERRED EMBODIMENTS

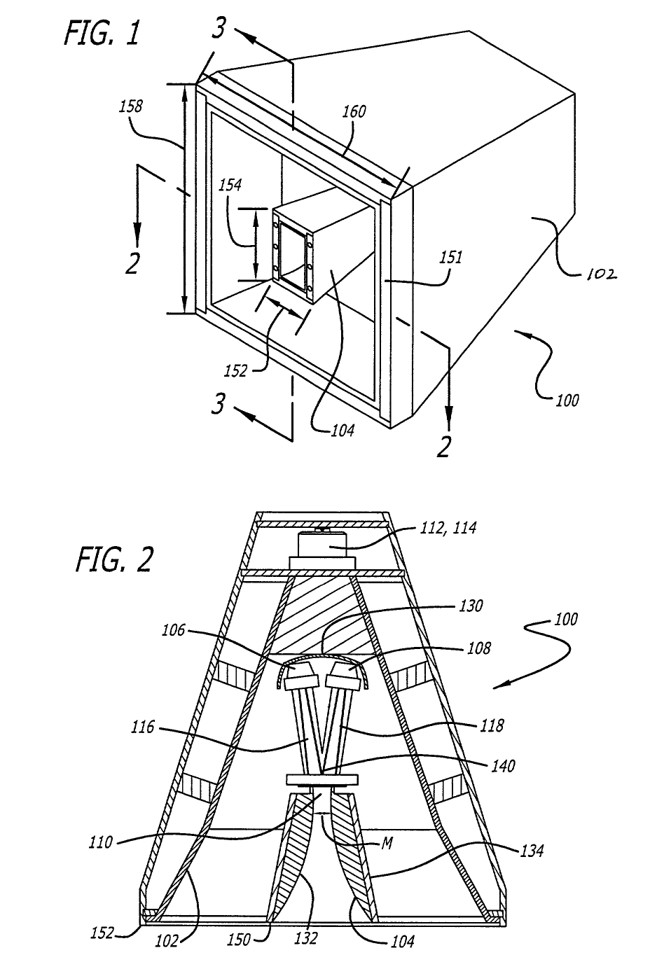

FIGS. 1 through 3 illustrate a sound system 100 incorporating a midrange horn 102 with a high frequency (HF) horn 104 to increase the SPL while minimizing interference problems. The sound system 100 may include the following features: (1) a HF horn 104 coupled to a plurality of high frequency drivers 106 and 108 where they sum or merge into a common throat 110 or wave guide; (2) coaxially mounting the midrange horn 102 with the HF horn 104, where the midrange horn 102 is coupled to a plurality of midrange drivers 112 and 114; and (3) mounting the plurality of midrange drivers 112 and 114 generally perpendicular to the plurality of HF drivers 106 and 108.

The HF horn 104 may be coaxially positioned within the mouth of the midrange horn 102. A number of channels 156 may be used to coaxially couple the HF horn 104 to the midrange horn 102. A plurality of diffraction slots 116 and 118 may be between the plurality of HF drivers and the HF horn. The plurality of diffraction slots 116 and 118 may couple the HF drivers 106 and 108 to the HF horn 104. The plurality of slots 116 and 118 may merge to form a common exit 140 that is adapted to mate with the throat 110 of the HF horn 104.

The cross-section of the plurality of slots 116 and 118 may have a variety of shapes such as rectangular, square, triangular, oval, and circular. As the plurality of slots 116 and 118 merge, the common exit may have a variety of cross-sectional shapes as well such as rectangular, square, triangular, oval, and circular. The plurality of slots 116 and 118 may be sized so that the acoustical output of the plurality of slots may be fully coherent. In this configuration, the wave fronts from the plurality of slots may be in phase so that the summation of the acoustic wave fronts occurs at frequencies between about 500 Hz and about 20 kHz. The summation may also occur at angles within the nominal horizontal and vertical coverage range of the horns.

The plurality of slots 116 and 118 may expand in area gradually from the HF driver's side to the throat 110 of the HF horn 104. The cross-sectional area may increase smoothly without discontinuities in the growth rate. The cross-sectional area may grow approximately in an exponential or other desirable manner. The HF horn 104 and the midrange horn 102 may expand gradually as well until they both form a HF lip 150 and a midrange lip 152, respectively. This allows the wave fronts from the HF drivers and midrange drivers to propagate in a smooth manner.

As illustrated in FIG. 2, the HF horn 104 may be configured so that it does not interfere with the expansion of the midrange horn 102 for proper acoustic loading. The HF horn 104 may be designed with both an interior surface 132 and a molded outer surface 134. The outside surface 134 may expand to maintain the area growth of the midrange horn 102 in an exponential manner. The space between the inside and outside surfaces 132 and 134 may be filled with urethane foam that provides structural rigidity and acoustic damping.

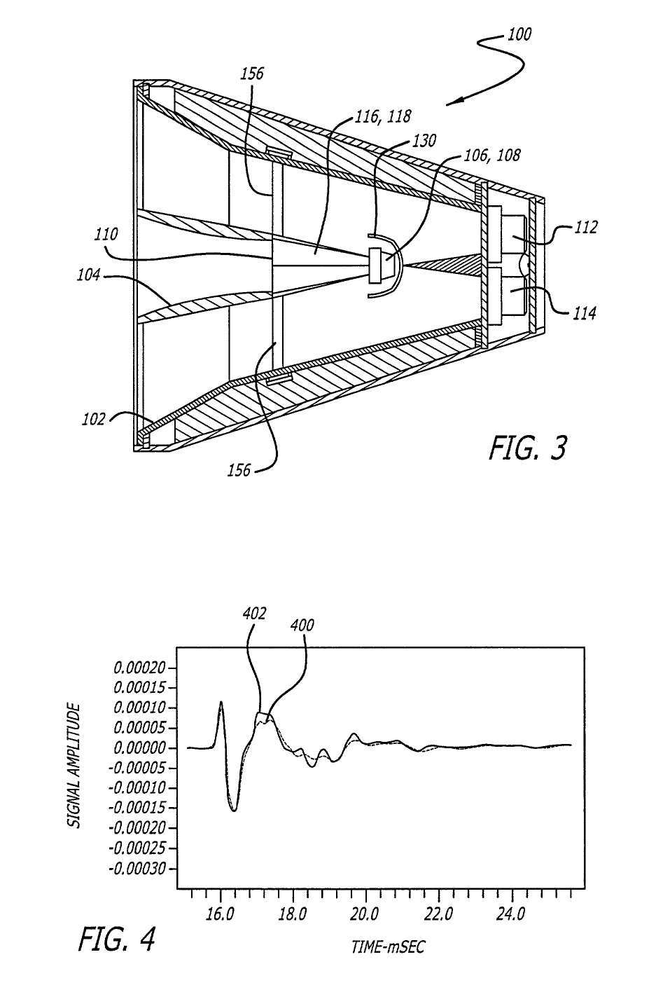

FIGS. 2 and 3 illustrate the midrange horn 102 may be coupled to two midrange drivers 112 and 114, where the two midrange drivers 112 and 114 are aligned so that they are substantially perpendicular to the two HF drivers 106 and 108 that are aligned. The midrange drivers may be sized and spaced apart from each other so that the acoustic summed response may be fully coherent as well. For example, the centerline to centerline distance between the midrange drivers may be about 6.5 inches (165 mm) and about 12 inches (305 mm); and in certain applications the center of the two midrange drivers may be spaced about 8.5 inches (216 mm) apart. This allows the summation of the acoustic wave fronts to occur at frequencies between about 20 Hz and about 20 kHz. The summation of the wave fronts may also occur at angles within the nominal horizontal and vertical coverage range of the horn. The midrange driver may generate wave fronts with frequencies between about 20 Hz and about 3 kHz. The diameter of the midrange drivers may be about 8 inches (203 mm) as described in U.S. Pat. No. 5,748,760, and is incorporated by reference.

The HF drivers 106 and 108 may be placed close to the midrange drivers so the reflection of the wave fronts from the midrange drivers 112 and 114 off the backside of the HF drivers 106 and 108 is minimized. At higher frequency levels, wave fronts between about 500 Hz and 2.0 kHz from the midrange drivers 112 and 114 may reflect off the back of the HF drivers 106 and 108. This may cause the sound waves to reflect back to the throat of the midrange horn 102, causing aberration in the frequency and polar response. To minimize or eliminate such reflections, an acoustic throat damper 130 may be used to wrap around the HF drivers 106 and 108. The damper 130 may be specified to be moderately acoustically absorptive above 700 Hz, but not to be absorptive below 700 Hz. Hence, the portion of the wave fronts between 500 Hz and 2.0 kHz that would be reflected from the rear of HF drivers 106 and 108 are absorbed by the damper 130 rather than reflecting back into the midrange horn 102. The damper 130 may be constructed with an inside and outside shell of flame-retardant-treated and acoustically transparent woven fabric. The damper 130 may be made of fiberglass wool, grill cloth, Dacron, or any other material known to one skilled in the art.

FIG. 4 illustrates the midrange impulse response with and without the damper 130. The solid curve 400 indicates the response with the damper 130, and the dash curve 402 indicates the response without the damper 130. The solid curve 400 shows a smoother polar response and cleaner impulse response than the dash curve 402. FIG. 4 also indicates that since the damper 130 is absorptive above 700 Hz, there may be a net reduction in the SPL of about 1 dB between frequency range of about 1 kHz and 2 kHz. The damper 130 is optional depending on the application considering the trade off between the 1 dB reductions in the SPL versus smoother responses.

Shadowing may occur if the HF horn 104 blocks too much area of the midrange horn 102. This can cause the midrange horn 102 to behave as distinct “cells.” When this happens, the midrange off-axis response may have nulls within the nominal coverage angle due to destructive interference of the acoustic energy produced by the distinct cells. This effect may be minimized by reducing the size of the HF horn 104. On the other hand, the size of the HF horn 104 needs to be large enough to maintain a pattern control at the crossover because the lower frequency limit of desirable pattern control may be limited by the mouth size of the HF horn.

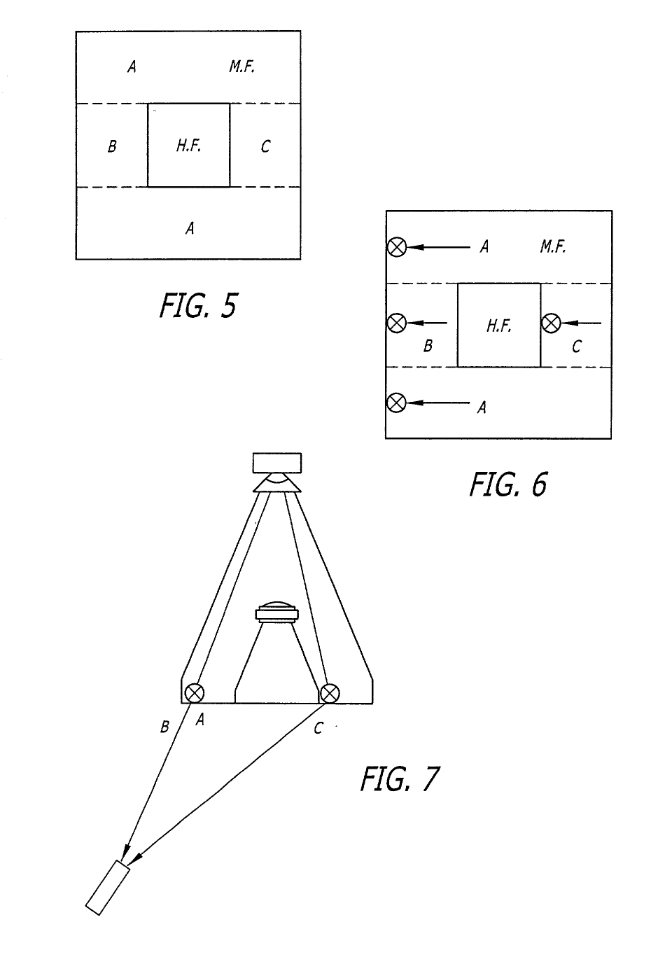

FIGS. 5 through 7 illustrate the effect of shadowing that causes the midrange horn to be divided into separate acoustical radiating areas. In this example there are three distinct areas defined by: two large areas labeled “A” formed above and below the HF horn; and two smaller areas “B” and “C” formed on both sides of the HF horn. FIGS. 6 and 7 illustrate that the listening or measurement location may be moved to the left, as indicated by the left arrows. In such instances, sound must travel through the vector (X) shifted to the sidewall of the horn. At this angle of observation, acoustic energy originating from areas “A” and “B” may be in the same vertical plane, but energy arriving from area “C” may be offset in time. If the “shadowed” area or area “C” is too large the difference in arrival time may cause narrowing of the beamwidth, and visible lobing in the polar response may occur. Similarly, the same effect may occur in the vertical plane.

The effect of shadowing may be minimized if the height 158 and width 156 of the HF horn 104 is about 0.25 to about 0.4 ratio of the height 158 and width 160 of the midrange horn 102, respectively. This means that the masked area “C” may be between about 13% and about 19% of the total radiating area of the midrange horn. For 13% masked area and 19% mask area, there may be about 2 dB and about 4 dB maximum variations in response, respectively, assuming the following: (1) the intensity of the sound field is uniform across the radiating area of the midrange horn; and (2) the energy radiating from the “shadowed” zone is shifted 180° out-of-phase compared to the primary arrival of energy at some frequencies. If the HF horn is not square, then the percentage of masking may be different. With reference to FIGS. 1 through 3, the ratio between the HF horn 104 versus the midrange horn 102 may be about 0.33 vertically, and about 0.28 horizontally.

The output from the two midrange drivers 112 and 114 may be combine coherently so that the SPL may increase up to 6 dB in the coverage area. The midrange drivers may be JBL's 2250J Neodymium Differential Drives having a diameter of about 200 mm (8 in.) that provides about 350 watt power handling, per transducer. Other midrange drivers with different diameters may be used with this invention. Using two 200 mm (8 in.) diameter midrange drivers allows the bandwidth of the driver to extend to higher frequencies. The two smaller diameter drivers may also be placed edge-to-edge where the centerline to centerline distance is between about 7 inches (178 mm) and 8¼ inches (210 mm) apart. This minimizes the off-axis interference in the dual driver system.

FIG. 3 illustrates the midrange drivers aligned edge-to-edge vertically so that the HF drivers 106 and 108 may be located between the two-midrange drivers 112 and 114. Arranging the high and midrange drivers in this configuration may reduce the masked area due to the HF drivers being in front of the midrange drivers. The two HF drivers may be JBL's compression drivers Model 2430 or 2435, both manufactured at 8500 Balboa Blvd. Northridge, Calif. 91329, U.S.A. In this regard, U.S. patent application Ser. No. 09/921,149 entitled Two-Stage Phasing Plug System in a Compression Driver, and filed on Jul. 31, 2001, is incorporated by reference. The driver Model No. 2430 may be used with a diaphragm made of aluminum, and the driver Model No. 2435 may be used with a diaphragm made of Beryllium. These HF drivers may be relatively small yet able to produce high acoustical output due to their efficiency, and they may generate wave fronts with a frequency range between about 500 Hz and about 20 kHz. Both the 2330 and 2435 may have a 4¼ inches (108 mm) diameter with a 3 inch (75 mm) diaphragm, and a height of about 2 5/16 inches (67 mm). In contrast, traditional large format high frequency compression drivers may have a diameter ranging from 6.5 inches (165 mm) to 10 inches (254 mm). This means that the rear side of the HF drivers 106 and 108 that face the midrange drivers, have relatively smaller surface areas so that they minimize wave fronts from the midrange drivers 112 and 114 from reflection off the HF drivers 106 and 108. HF drivers having a diameter size of other than 5.5 inches (140 mm) may be used to minimize reflecting of the wave fronts from the midrange drivers.

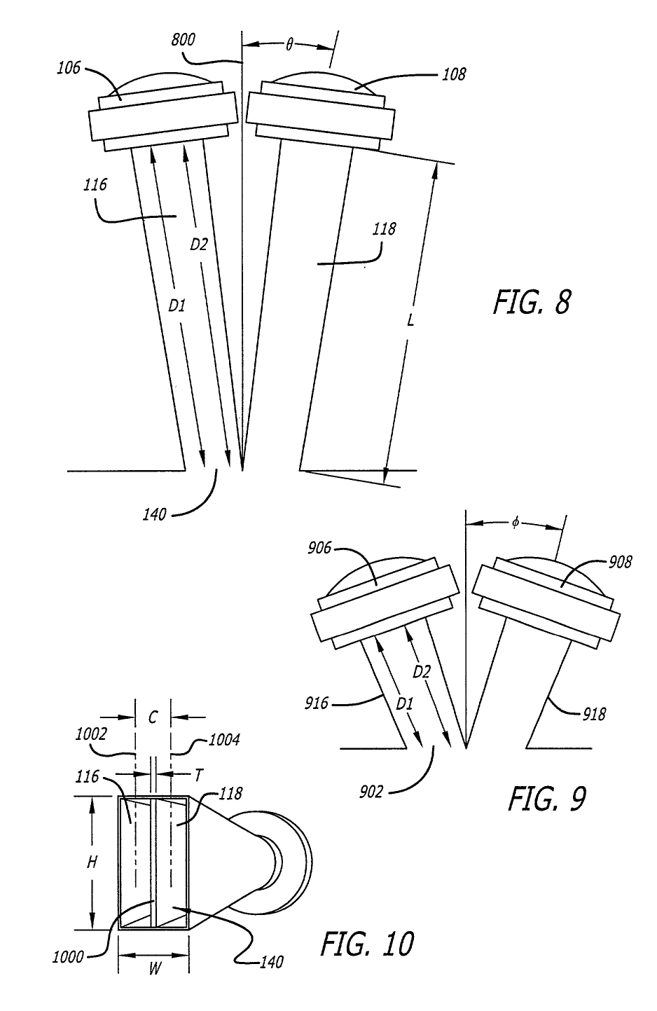

FIG. 8 illustrates two 4¼ inch diameter HF drivers 106 and 108 coupled to its respective slots 116 and 118. FIG. 9 illustrate two traditional HF drivers 906 and 908 having a diameter between 6.5 inches (165 mm) and 10 inches (254 mm) coupled to its respective slots 916 and 918. Because of the larger diameter of traditional drivers 906 and 908, the half-included angle φ for slots 916 and 918 is greater than the half-included angle θ for the slots 116 and 118. This means that the offset arrival of the wave front at the common exit 140 (D2 minus D1) for the slots 116 and 118 is less than at the common exit 902. Accordingly, minimizing the included angle between the HF drivers also minimizes the path length difference (D2 minus D1) to the common exit. Using smaller HF drivers may reduce the half-included angle to minimize the path length difference.

FIG. 10 illustrates the two slots 116 and 118 merging to form a common exit 140. The total width “W” for the common exit 140 may between about 0.75 inches (19 mm) and about 3.00 inches (76 mm); and the total height “H” may be between about 0.5 and 30.0 inches (13 mm and 762 mm). The distance “C” between the two centerlines 1002 and 1004 through the respective slots 116 and 118 may be between about 0.5 inches (13 mm) and 3.0 inches (76 mm). The common exit 140 may be divided by a wall 1000 having a thickness “t” that is between about 0.06 inches (2 mm) and about 0.25 inches (6 mm). As further illustrated in FIG. 8, the length “L” for the two slots 116 and 118 may be between about 4.0 inches (102 mm) and about 30.0 inches (762 mm). In particular, the length “L” may be about 11.0 inches (279 mm).

Using smaller diameter HF drivers 106 and 108 allows the two slots 116 and 118 to merge so that the distance “C” between the centerline to centerline at the common exit may be small. This allows the wave fronts from the two HF drivers 106 and 108 to sum coherently at the common exit. For example, for the two slots 116 and 118 having the following dimensions: L=11 inches (279 mm); W=2.12 inches (54 mm); C=1.0 inch (25 mm); and t=0.12 inches (3 mm), the included angle θ between the primary axis 800 and the slots may be about 8.5° . This may reduce the offset in arrival of the wave front (D2 minus D1) at the common exit 802 to about 3.5 mm (0.14 in.). This may translate into about 63 μsec offset in arrival.

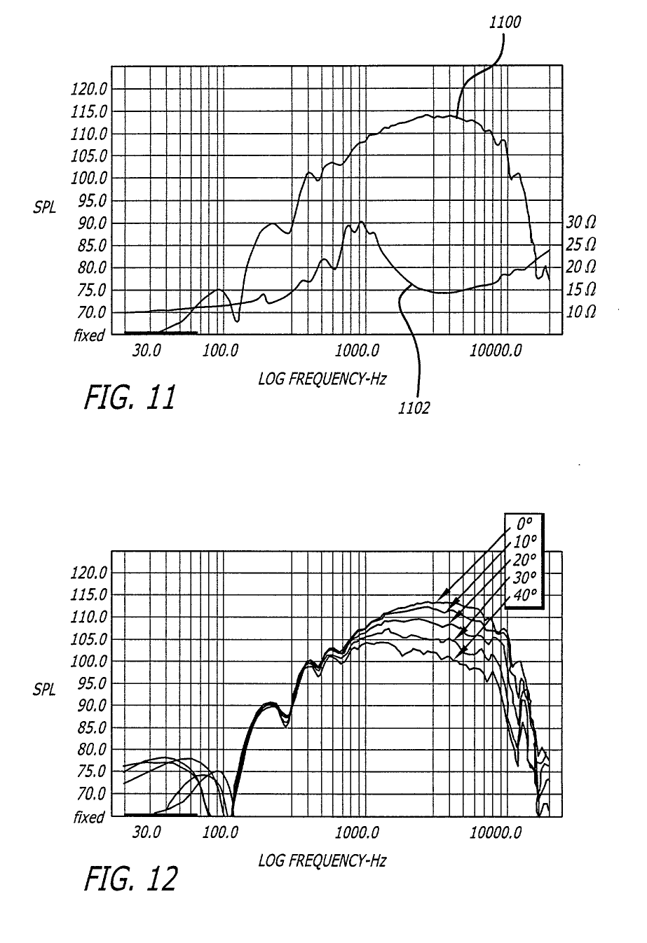

As illustrated in FIG. 2, the common exit 140 may be coupled to the throat 110 of the HF horn 104. The curvature of the inner surface 132 may be smoothly curved in shape where the minimum horizontal width “M” may be about 45 mm (1/4 in.), that is about 0 to about 6 inches (152 mm) in front of the common exit 140. The HF horn 104 integrates the two wave fronts from the two HF drivers 106 and 108 in a coherent fashion. FIG. 11 illustrates an unprocessed frequency response curve 1100 and an impedance curve 1102 of the high frequency section. Note the smooth frequency response throughout the entire usable piston band of the HF drivers. The response is substantially free of performance aberrations to frequencies above 11 kHz. FIG. 12 shows the horizontal off-axis response for the same horn. These curves further illustrate that the two HF drivers 106 and 108 and the HF horn 104 behave substantially as a single unified signal source beyond 16 kHz at 0°, 10°, 20°, 30° and 40° off axis.

The sound system 100 may behave symmetrically through horizontal and vertical crossover regions. Such symmetry may provide a degree of freedom in the crossover design. In a non-coaxial system, where the HF horn is displaced to one side of the midrange horn, the two pass bands may need to be in phase and at a level of −6 dB at the crossover point. For a symmetrical loudspeaker, however, the crossover region may be manipulated to optimize the system response both on and off axis to achieve substantially consistent frequency response at angles along the on and off-axis, horizontally and vertically.

Signal processing may improve the performance of the sound system 100. The performance may be improved by tuning a number of variables in a digital loudspeaker processor such as: (1) Crossover frequency; (2) High pass filter slope; (3) High pass filter type; (4) low pass slope; (5) low pass filter type; (6) interchannel delay; (7) polarity; and (8) all-pass filtering. Each of these variables may be optimized to yield a desired result. Tuning may be available through such processors as: JBL DSC-260, BSS Soundweb, and dbx Driverack.

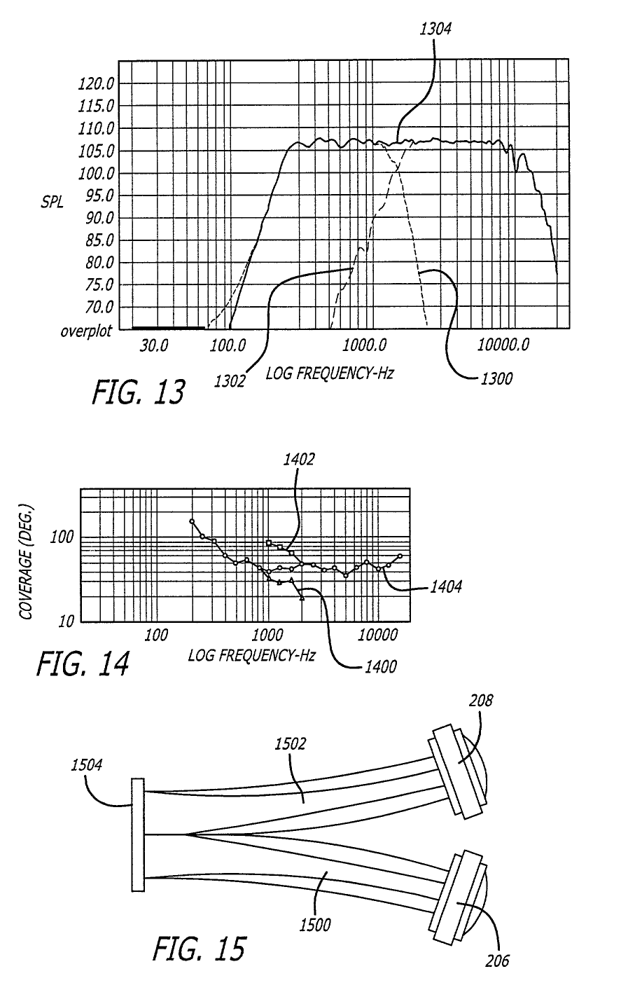

The filter slopes and alignments may allow the interaction between the pass-bands to be controlled. By determining the correct amount of interaction to occur at each frequency, the beamwidth, and directivity interaction between the pass-bands may be adjusted to assume the characteristic of either pass-band at each frequency. FIG. 13 illustrates a high-resolution frequency response plot of the processed midrange frequency band 1300, high frequency band 1302, and the net system response 1304 for the sound system 100 using the signal processing. The net result is a clean system response 1304 based on the contribution from the midrange and high frequency bands 1300 and 1302.

FIG. 14 illustrates three horizontal beamwidth curves: unprocessed midrange section beamwidth 1400; unprocessed high frequency beamwidth 1402; and the overall horizontal beamwidth 1404 that has been processed to optimize the performance of the sound system 100. With the signal processing there is a more uniform angular and frequency response coverage.

Alternatively, as illustrated in FIG. 15, two slots 1500 and 1502 may be curved in certain applications to produce a flatter wave front as the common exit 1504. With the curve slots, as the two curve slots merge they are more parallel with each other so that the wave fronts from the HF drivers may be flatter. This may be desirable depending on the required horizontal coverage angle. The radius of curvature of the two slots may be such that the two HF drivers are as close to each other as possible to minimize interfering with wave fronts from the midrange drivers. The length of the two slots may determine the vertical coverage angle.

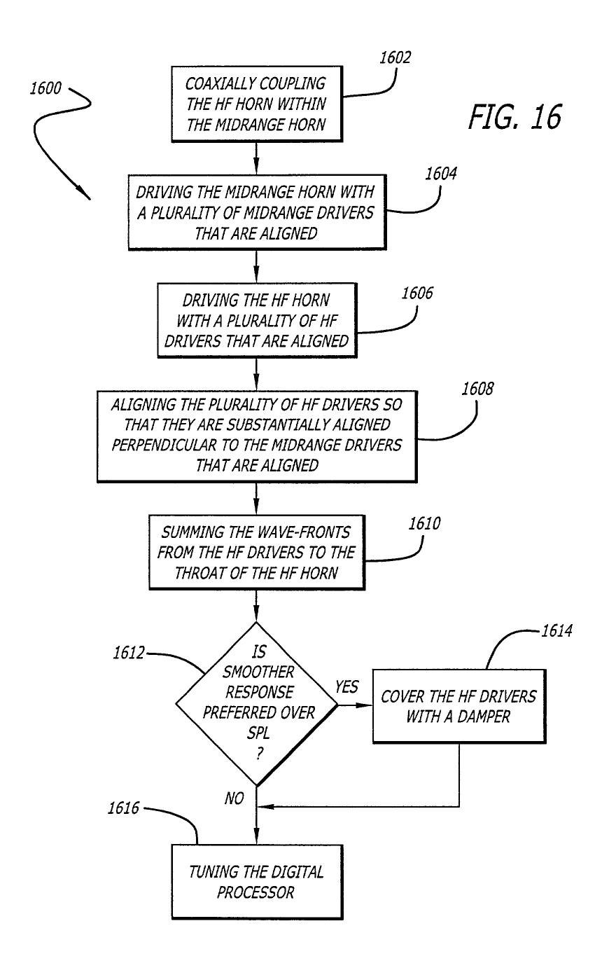

FIG. 16 illustrates a method 1600 for grouping a plurality of midrange drivers and a plurality of high frequency drivers in an enclosure to increase SPL while minimizing interference problems. In 1602, the HF horn 104 may be coaxially coupled to the midrange horn. In 1604, a plurality of midrange drivers 112 and 114 that are aligned may drive the midrange horn 102. In 1606, a plurality of HF drivers 106 and 108 may drive the HF horn within the midrange horn. In 1608, the plurality of HF drivers may be aligned so that they are substantially perpendicular to the midrange drivers that are aligned. In 1610, the wave fronts from the plurality of HF drivers may be coherently summed into the throat of the HF horn. In 1612, if smoother response is preferred over 1 dB reduction in SPL, then in 1614, a damper may be used to cover the HF drivers so that the wave fronts above about 700 Hz which may reflect off drivers are absorbed rather than reflecting back off the HF drivers. In 1614, a digital loudspeaker may be tuned to improve the performance of the sound system.

While various embodiments of the invention have been described, it will be apparent to those of ordinary skill in the art that many more embodiments and implementations are possible within the scope of this invention. Accordingly, the invention is not to be restricted except in light of the attached claims and their equivalents.

What is claimed is:

1. A sound system, comprising:
a high frequency (HF) horn coaxially coupled to a midrange horn, where the HF horn has a throat within the midrange horn;
two slots merging to form a common exit, where the common exit is coupled to the throat of the HF horn;
two midrange drivers coupled to the midrange horn; and
two HF drivers coupled to the two slots, respectively, where the two HF drivers are substantially perpendicular to the two midrange drivers.

2. The sound system according to claim 1, further including a damper covering the two HF drivers, where the damper is partially acoustically absorptive above about 700 Hz.

3. The sound system according to claim 1, where the cross-section of the common throat is rectangular.

4. The sound system according to claim 1, where the two slots expand smoothly in a cross-sectional area.

5. The sound system according to claim 1, where the HF horn and the midrange horn each have a height and a width, where the height and width of the HF horn is about 0.25 to about 0.4 ratio of the height and width of the midrange horn, respectively.

6. The sound system according to claim 1, where the HF horn has a HF lip and the midrange horn has a midrange lip, and where both the HF lip and the midrange lip have a rectangular shape.

7. The sound system according to claim 1, where an area between the HF horn and the midrange horn is a radiating area for the midrange horn, and to one side of the HF horn defines a mask area, where the mask area is about 13% to about 19% of the radiating area.

8. The sound system according to claim 1, where an area between the HF horn and the midrange horn is a radiating area for the midrange horn, and to one side of the HF horn defines a mask area, where the mask area is at least about 13% of the radiating area.

9. The sound system according to claim 1, where an area between the HF horn and the midrange horn is a radiating area for the midrange horn, and to one side of the HF horn defines a mask area, where the mask area is less than 19% of the radiating area.

10. The sound system according to claim 1, further including a signal processor for tuning the sound system.

11. A sound system, comprising:
a high frequency (HF) horn coaxially coupled within a midrange horn, where the HF horn is driven by a plurality of HF drivers; and
a plurality of midrange drivers coupled to the midrange horn, where the plurality of HF drivers are aligned so that they are substantially perpendicular to the plurality of the midrange drivers that are aligned.

12. The sound system according to claim 11, further including a plurality of slots coherently summing wave fronts from the plurality of HF drivers to a throat of the HF horn.

13. The sound system according to claim 11, further including a damper adapted to cover the plurality of HF drivers and to be partially acoustically absorptive of wave fronts above about 700 Hz.

14. The sound system according to claim 12, where the throat has a rectangular shape.

15. The sound system according to claim 11, where the HF horn and the midrange horn each have a height and a width, where the height and width of the HF horn is about 0.25 to about 0.4 ratio of the height and width of the midrange horn, respectively.

16. The sound system according to claim 11, where the HF horn has a HF lip and the midrange horn has a midrange lip, where both the HF lip and the midrange lip have a rectangular shape.

17. The sound system according to claim 11, where an area between the HF horn and the midrange horn is a radiating area for the midrange horn, and to one side of the HF horn defines a mask area, where the mask area is about 13% to about 19% of the radiating area.

18. The sound system according to claim 12, further including two curved slots.

19. A sound system, comprising:
a high frequency (HF) horn coaxially coupled within a midrange horn, where the midrange horn is coupled to a plurality of midrange drivers;
means for driving a plurality of HF wave fronts toward the HF horn without substantially reflecting midrange wave fronts from the midrange drivers back into the midrange horn; and
means for summing the plurality of HF wave fronts to a throat of the HF horn.

20. The sound system according to claim 19, further including means for partially acoustically absorbing the midrange wave fronts from the midrange drivers above about 700 Hz.

21. The sound system according to claim 19, where the means for summing the plurality of HF wave fronts comprises two slots merging to form a common throat with the throat of the HF horn, and where the two slots connect to the two HF drivers, respectively.

22. The sound system according to claim 19, where the two HF drivers are aligned within the midrange horn so that they are substantially perpendicular to the two midrange drivers that are aligned.

23. A method for grouping a plurality of midrange drivers and a plurality of high frequency drivers, comprising:
coupling coaxially a high frequency (HF) horn within a midrange horn;
driving the midrange horn with a plurality of midrange drivers that are aligned;
summing wave fronts from a plurality of HF drivers to a throat of the HF horn; and
aligning the plurality of HF drivers so that they are substantially perpendicular to the plurality of midrange drivers that are aligned.

24. The method according to claim 23, further including absorbing wave fronts above about 700 Hz from the plurality of midrange drivers around the plurality of HF drivers.

25. The method according to claim 23, further including tuning a digital loudspeaker processor to provide a clean system response.
